(19) United States
(12) Patent Application Publication
(10) Pub. No.: US 2004/0175905 A1
(43) Pub. Date: Sep. 9, 2004

(54) Method of forming thin film using atomic layer deposition

(76) Inventors: Seok-Jun Won, Seoul (KR); Yong-Kuk Jeong, Seoul (KR); Dae-Jin Kwon, Seoul (KR)

Correspondence Address: MARGER JOHNSON & McCOLLOM, P.C., 1030 S.W. Morrison Street, Portland, OR, 97205, US

(21) Appl. No.: 10/793,715

(22) Filed: Mar. 3, 2004

(30) Foreign Application Priority Data
Mar. 4, 2003 (KR) 03-13428

(51) Int. Cl. C23C 16/00; H01L 21/20

(52) U.S. Cl. 438/478

(57) ABSTRACT

Provided is an atomic layer deposition (ALD) method for forming a thin film using two types of reactants that are different in surface adsorptivity for a source material. According to the ALD method, first, a source material is fed into a reaction chamber and then undergoes first purging. Next, a first reactant with good surface adsorptivity for the source material and a second reactant with poor surface adsorptivity for the source material are fed into the reaction chamber. The second reactant may be fed simultaneously with the first reactant or after the purging of the first reactant. Next, a radio frequency is applied to the reaction chamber to thereby transform the second reactant into a plasma state. Next, the reaction chamber is subjected to a second purging. If the thickness of a deposited film is not sufficient, the above-described processes are repeated.

### CROSS REFERENCE TO RELATED APPLICATIONS

This application claims priority from Korean Patent Application No. 2003-13428, filed on Mar. 4, 2003, in the Korean Intellectual Property Office, the disclosure of which is incorporated herein by reference in its entirety.

### BACKGROUND OF THE INVENTION

1. Field of the Invention

This disclosure relates to a method of forming a thin film, and more particularly, to a method of forming a thin film using atomic layer deposition (ALD).

2. Description of the Related Art

Thin films are very important in various technical fields including insulating layers and active layers of semiconductor devices and transparent electrodes of liquid crystal display devices. In particular, in ultra-highly integrated circuits and display devices, there has been an increasing need to form thin films having a uniform thickness of several nm to several tens of nm. In semiconductor devices, there is a need for precise control technologies for ultra thin films in dielectric films for memory applications, diffusion prevention films, and gate dielectric films.

Atomic layer deposition (ALD) is a process of forming a thin film using chemical substitution caused upon cyclic supply of a source material and a reactant. As used herein for formation of a thin film using ALD, the term, “source material” refers to a chemical substance that is initially applied to a substrate or a deposited thin film and the term, “reactant” refers to a chemical substance that chemically reacts with the source material. A compound formed by chemical substitution upon ALD can be controlled in an atomic layer unit. Therefore, a thin film can be formed and the thickness of the thin film can be easily controlled by ALD. Furthermore, even in a large-sized substrate, a film with uniform thickness can be formed by ALD. Still furthermore, ALD ensures excellent step coverage regardless of topography of a substrate.

FIG. 1 is a flowchart illustrating a conventional process of forming a thin film using conventional ALD and FIG. 2 is a timing diagram illustrating a supply scheme for a source material and a reactant according to the process shown in FIG. 1. Hereinafter, an example ALD method of forming an Hf₂O film using HfCl₄ as a source material and H₂O as a reactant will be illustrated.

Referring to FIGS. 1 and 2, a source material is first fed into a reaction chamber (not shown), in which a substrate is loaded, for a predetermined time (t11) (step S11). As described above, HfCl₄ is used as the source material. A supply time (t11) for the source material is set to about 0.1 seconds. A part of the source material is reactively adsorbed or chemisorbed on the surface of the substrate. On the other hand, the remnant of the source material is physisorbed on the surface of the reactively adsorbed or chemisorbed source material or remains inside the reaction chamber.

Next, the reaction chamber is subjected to first purging for a predetermined time (t₁₂) (step S12). Duration (t₁₂) of the first purging is set to about 0.9 seconds. In the first purging, the remnant of the source material that is not reactively adsorbed or chemisorbed on the substrate is removed from the reaction chamber.

Next, a reactant is fed into the reaction chamber for a predetermined time (t₁₃) (step S₁₃). As described above, H₂O is used as the reactant. As a result of the reaction of HfCl₄ and H₂O, an Hf₂O film layer is formed on the surface of the substrate. H₂O has very good surface adsorptivity, and thus, immediately reacts with the reactively adsorbed or chemisorbed source material. Therefore, use of H₂O as the reactant can reduce a time required for one cycle. For example, the reactant supply time (t₁₃) may be about 0.1 seconds.

Next, the reaction chamber is subjected to second purging for a predetermined time (t₁₄) (step S14). Duration (t₁₄) of the second purging is also set to about 0.9 seconds. In the second purging, reaction byproducts including an HCl gas except for the Hf₂O film deposited on the substrate are removed from the reaction chamber. This completes one cycle for formation of the Hf₂O film.

Next, whether the Hf₂O film thus formed has a predetermined thickness is determined (step S15). If the thickness of the Hf₂O film is not a predetermined thickness, steps S11 through S14 are repeated. However, if the thickness of the Hf₂O film is a predetermined thickness, the thin film formation process using ALD is terminated and the substrate is unloaded from the reaction chamber.

As described above, use of H₂O as a reactant can reduce process duration due to excellent surface adsorptivity of H₂O. Reduction of process duration increases productivity, thereby reducing a production cost. However, when H₂O is used as a reactant, there arises a problem in that an OH radical remains in a deposited film. Due to such a residual OH radical, undesired chemical reaction may occur, and thus, impurities such as Hf (OH)₂ may be left in a deposited film. If such impurities are left in a thin film, it is difficult to form a good thin film with desired characteristics. For example, when a Hf₂O film including Hf (OH)₂ as an impurity is used as a dielectric film for a semiconductor device, a large amount of leakage current is generated due to the impurity.

Embodiments of the invention address these and other disadvantages of the conventional art.

### SUMMARY OF THE INVENTION

Embodiments of the present invention provide methods of forming a thin film using atomic layer deposition (ALD). According to these methods, even when a reactant with good surface adsorptivity due to a hydrogen group contained therein is used, impurities are little contained in the film. Therefore, in addition to good productivity, the formed film has excellent electrical properties.

### BRIEF DESCRIPTION OF THE DRAWINGS

The above and other features and advantages of the present invention will become more apparent by describing in detail exemplary embodiments thereof with reference to the attached drawings.

FIG. 1 is a flowchart illustrating a conventional method of forming a thin film using ALD.

FIG. 2 is a timing diagram illustrating the supply scheme of a source material and a reactant in a conventional ALD process.

FIG. 3 is a flowchart illustrating a method of forming a thin film using ALD according to some embodiments of the invention;

FIG. 4 is a timing diagram illustrating the supply scheme of a source material, first and second reactants, and the period for transformation of the second reactant into a plasma state in a method of forming a thin film using ALD according to an embodiment of the invention.

FIG. 5 is a timing diagram illustrating the supply scheme of a source material, first and second reactants, and the period for transformation of the second reactant into a plasma state in a method of forming a thin film using ALD according to another embodiment of the invention.

FIG. 6 is a timing diagram illustrating the supply scheme of a source material, first and second reactants, and the period for transformation of the second reactant into a plasma state in a method of forming a thin film using ALD according to still another embodiment of the invention.

FIG. 7 is a comparative graph illustrating leakage current characteristics of Hf2O films according to a conventional process and according to an embodiment of the invention.

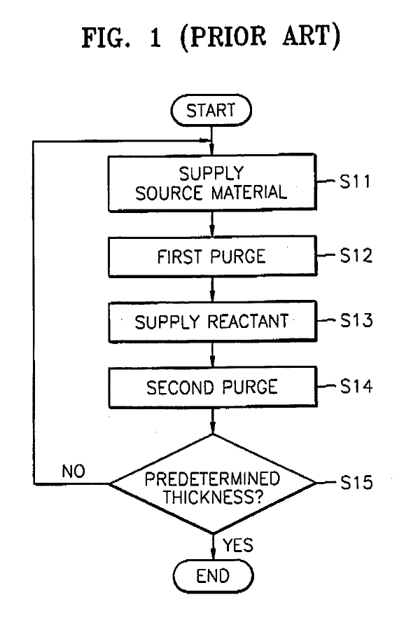

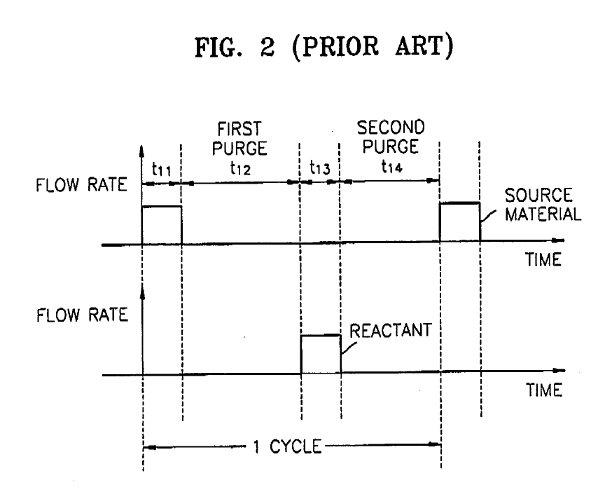

### DETAILED DESCRIPTION OF THE INVENTION

Hereinafter, preferred embodiments of the invention will be described in detail with reference to the accompanying drawings. Throughout the specification, the same reference numerals indicate the same constitutional elements.

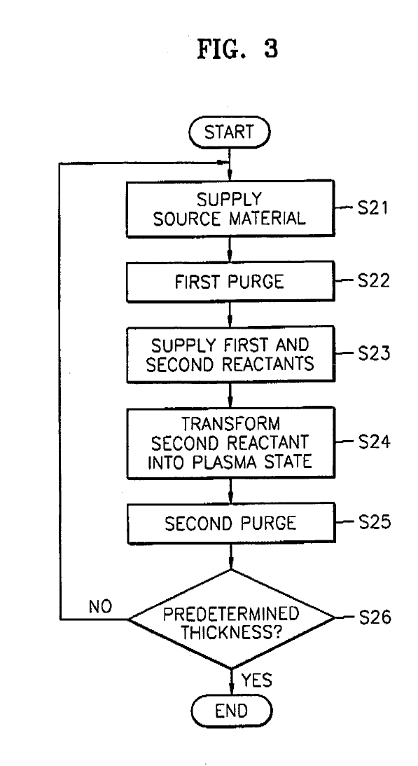

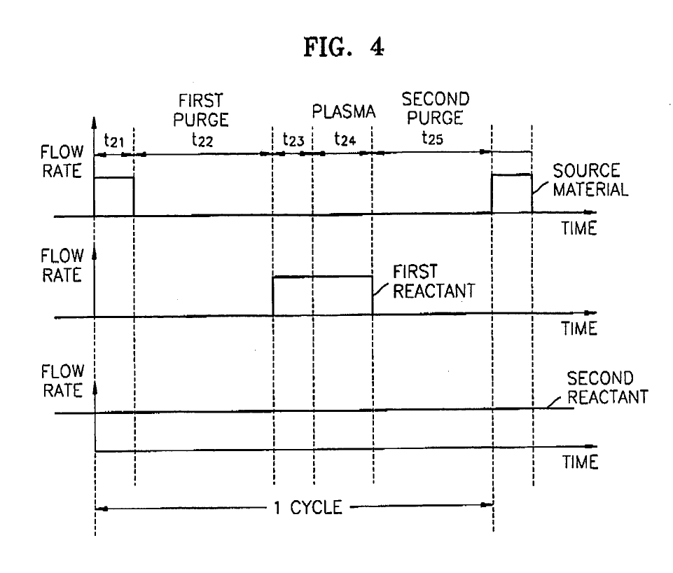

FIG. 3 is a flowchart illustrating a method of forming a thin film using ALD according to some embodiments of the present. FIG. 4 is a timing diagram illustrating the supply scheme of a source material, first and second reactants and the period for transformation of the second reactant into a plasma state according to embodiments of the invention.

Referring to FIGS. 3 and 4, a source material is fed into a reaction chamber (not shown), in which a substrate is loaded, for a predetermined time (t₂₁) (process S21). The source material may vary depending on the type of a thin film to be formed. For example, in the case of forming a metal oxide film, a metal nitride film, or a metal nitride oxide film as a metal dielectric film, a compound containing a corresponding metal may be used as the source material. For instance, the source material may be a chlorine (Cl)-containing compound, for example, HfCl₄, TaCl₄, TiCl₄, or HfCl₄. In addition, the source material may also be a metal organic compound such as trimethyl aluminum (TMA).

During process S21, a part of the source material is reactively adsorbed or chemisorbed on the surface of the substrate or on the surface of a thin film formed in a previous ALD cycle. The remnant of the source material is physisorbed on the surface of the reactively adsorbed or chemisorbed source material or remains inside the reaction chamber.

Next, the reaction chamber is subjected to first purging for a predetermined time (t₂₂) (process S22). During the first purging, the residual source material that was not reactively adsorbed or chemisorbed on the surface of the substrate is removed from the reaction chamber.

Next, a reactant is fed into the reaction chamber (process S23). As for the reactant, a compound with good surface adsorptivity for the source material is used as a first reactant and a compound with poor surface adsorptivity for the source material is used as a second reactant.

For example, when the source material is a Cl-containing metal compound, the first reactant may be a hydrogen (H)-containing compound and the second reactant may be an H-free compound. On the other hand, when the source material is a metal organic compound such as TMA, the first reactant may be H₂O or O₃ and the second reactant may be O₂.

Use of a Cl-containing metal compound as the source material will now be described in more detail. When a thin film to be formed is a metal dielectric film, i.e., a metal oxide film, a metal nitride film, and a metal nitride oxide film, the first and second reactants can be used in the following combinations.

When forming a metal oxide film, H₂O can be used as the first reactant and O₂ as the second reactant. When a thin film to be formed is a metal nitride film, NH₃ can be used as the first reactant and N₂ as the second reactant. When a thin film to be formed is a metal nitride oxide film, H₂O or O₃ can be used as the first reactant and N₂ as the second reactant.

The first reactant is fed only for a predetermined time (t₂₃+t₂₄). However, as shown in FIG. 4, the second reactant can be continuously fed for the whole period of the ALD cycle, and not just for a predetermined time. Such continuous feeding of the second reactant is possible since the second reactant has poor surface adsorptivity for the source material. In particular, if the second reactant is continuously fed into the reaction chamber without being activated into a plasma state, the second reactant reacts only slightly with the source material.

Next, the second reactant is transformed into a plasma state (process S24). According to embodiments of the invention, the transformation of the second reactant into a plasma state is performed in the reaction chamber for ALD. That is, second reactant in a plasma state that is generated outside the reaction chamber (remote plasma gas) is not fed into the reaction chamber. To the contrary, the second reactant is fed into the reaction chamber and then activated into a plasma state inside the reaction chamber by radio frequency application. The radio frequency application is continued for a predetermined time (t₂₄) to thereby transform the second reactant into a plasma state.

Next, the reaction chamber is subjected to second purging for a predetermined time (t₂₅) (process S25). In the second purging, residual materials except for a film deposited on the surface of the substrate, i.e., residual first and second reactants, and a reaction byproduct are removed from the reaction chamber. This completes one ALD cycle for formation of a thin film on the substrate.

Next, during process S26, it is determined whether the thickness of the thin film thus formed is a predetermined thickness. If the thickness of the thin film is not a predetermined thickness, one full ALD cycle described above, i.e., processes S21 through S25, is repeated. However, if the thickness of the deposited thin film is a predetermined thickness, the thin film formation process using ALD is terminated, and the substrate is unloaded from the reaction chamber.

According to this embodiment of the invention, a thin film can be formed on a semiconductor substrate or a predetermined material film using two reactants with different properties. In particular, a metal dielectric film, (i.e., a metal oxide film, a metal nitride film, or a metal nitride oxide film) that has excellent electrical properties can be formed.

For example, if a thin film is a metal oxide film, the metal oxide film may be made of mono-metal oxide or multi-metal oxide. The mono-metal oxide for the metal oxide film may be Al₂O₃, TiO₂, Ta₂O₅, ZrO₂, HfO₂, Nb₂O₅, CeO₂, Y₂O₃, SiO₂, In₂O₃, RuO₂, or IrO₂, for example. The multi-metal oxide for the metal oxide film may be SrTiO₃, PbTiO₃, SrRuO₃, CaRuO₃, (Ba,Sr)TiO₃, Pb(Zr,Ti)O₃, (Pb,La) (Zr,Ti)O₃, (Sr,Ca) RuO₃, In₂O₃ doped with Sn, In₂O₃ doped with Fe, or In₂O₃ doped with Zr, for example.

If a thin film is a metal nitride film, the metal nitride film may be a TiN film, a TaN film, or a WN film, for example.

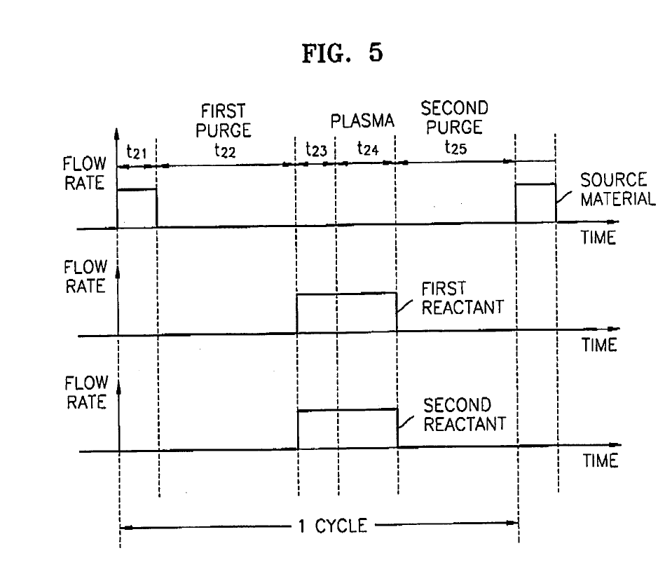

FIG. 5 is a timing diagram illustrating an example supply scheme of the source material, the first and second reactants, and the period for transformation of the second reactant into a plasma state according to another embodiment of the invention. The flowchart of FIG. 3 also applies to this embodiment.

Referring to FIGS. 3 and 5, the feeding of the source material (process S21) and the first purging (process S22) are as defined above for the previous embodiment. After the first purging, the first and second reactants are fed into the reaction chamber (process S23). The specific supply scheme of the first and second reactants is different from that of the above-described embodiment. However, the types of materials to be used as the first and second reactants and other process conditions may be the same.

As shown in FIG. 5, the first and second reactants are fed into the reaction chamber for a predetermined time (t₂₃+t₂₄). After a predetermined time (t₂₃) from the feeding of the first and second reactants, a radio frequency is applied to the reaction chamber to thereby transform the second reactant into a plasma state.

According to this embodiment, the second reactant is supplied to the reaction chamber prior to the second reactant being activated into a plasma state by the application of a radio frequency. Therefore, the second reactant in a plasma state can remove impurities in the thin film formed by the reaction of the source gas and the first reactant. Furthermore, since the second reactant is timely fed in an appropriate amount, the material cost can be reduced.

After the second reactant is transformed into a plasma state, the second purging is carried out. If necessary, the above-described processes are repeated to thereby form a thin film with a predetermined thickness.

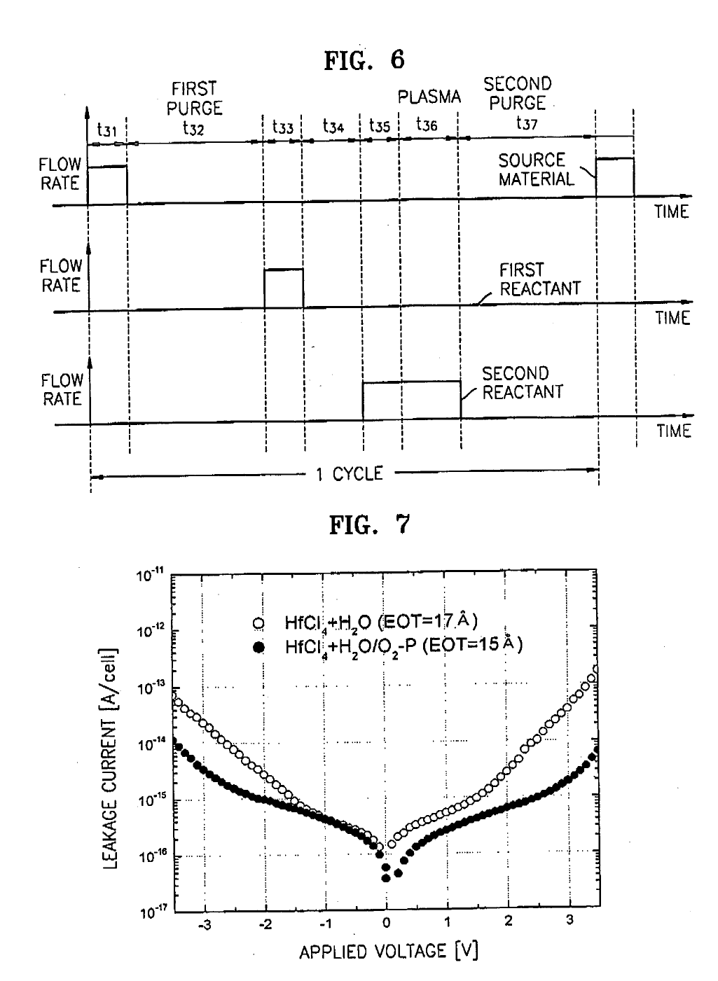

FIG. 6 is a timing diagram showing the supply scheme of the source material, the first and second reactants and the period for transformation of the second reactant into a plasma state according to yet another embodiment of the invention. The flowchart shown in FIG. 3 also applies to this embodiment.

Referring to FIGS. 3 and 6, the feeding of the source material (process S21) and the first purging (process S22) remain as defined in the previous embodiments. After the first purging, the first and second reactants are fed in the reaction chamber (process S23). The specific supply scheme of the first and second reactants is different from that of the previous embodiments. However, the types of materials to be used as the first and second reactants and other process conditions are the same.

As shown in FIG. 6, the first and second reactants are fed in sequence. That is, the first reactant is first fed into the reaction chamber for a predetermined time (t₃₃). At this time, the first reactant with good surface adsorptivity for the source material chemically reacts with the source material. During this process, impurities may be generated. Then, the first reactant and a reaction byproduct undergo purging for a predetermined time (t₃₄).

Next, the second reactant is fed into the reaction chamber for a predetermined time (t₃₅+t₃₆). Like the first embodiment described above, after a predetermined time (t₃₅) from the feeding of the second reactant, the second reactant is activated into a plasma state.

According to this embodiment, since the first reactant is purged and then the second reactant is fed, it is possible to more efficiently remove impurities left in a thin film upon reaction of the first reactant with the source material. Therefore, a thin film with excellent electrical properties can be formed. Furthermore, like the second embodiment described above, since the second reactant is timely fed in an appropriate amount, the material cost can be reduced.

Subsequent processes of formation of the second reactant into a plasma state remain as defined in the previous embodiments.

Hereinafter, an experimental example to which embodiments of the invention are applied will be described. This experimental example was carried out according to the first embodiment described above. However, it might be understood that the same process conditions as the first embodiment can be applied to the other embodiments and the same effects as the first embodiment can be obtained through the use of the other embodiments.

First, process duration for one ALD cycle was set to 2.3 seconds, which is about 0.3 seconds longer than a conventional ALD cycle, and thus, there is a little difference in process duration for one ALD cycle, when compared to a conventional ALD process. The time (2.3 seconds) required for one ALD cycle can be divided into the follows: t₂₁=0.1 seconds, t₂₂=0.9 seconds, t₂₃=0.1 seconds, t₂₄=0.3 seconds, and t₂₅=0.9 seconds.

A deposition temperature in the reaction chamber, i.e., a temperature of a wafer was set to about 300° C. and a temperature of a pipe for supply of the first and second reactants was set to about 250° C. A process temperature to be applied to this experimental example can be selected within a range of about 25 to 350° C. A pressure in the reaction chamber was set to 3 Torr. However, the pressure in the reaction chamber can be selected within a range of about 0.1 to 10 Torr.

In order to transform the second reactant into a plasma state, a radio frequency of 13.56 MHz was used. An electric power of 250 watts (W) was supplied. However, the electric power to be applied to this experiment example can be selected within a range of about 10 to 1,000 W. The electric power can vary depending on the type of the second reactant, the pressure and temperature of the reaction chamber, and the frequency of a radio frequency.

As an example of a conventional process, when 83 cycles of ALD was performed using HfCl₄ as a source material and H₂O as a reactant, an HfO₂ film with a thickness of 85 Å was formed. And, when O₂ plasma was used as a reactant, an HfO₂ film was only slightly deposited even though an ALD cycle was repeated several times. On the other hand, in this experimental example of an embodiment of the invention, when an ALD cycle was repeated 83 times, an HfO₂ film with a thickness of about 75 Å was deposited.

According to the embodiment of the invention, a film deposition rate was slightly reduced when compared to the conventional process described above. Therefore, productivity may be slightly reduced. However, the electrical properties, and in particular, the leakage current characteristics of a deposited film are superior to those obtained through the conventional process.

This result can be seen from the comparative graph shown in FIG. 7. FIG. 7 shows leakage current characteristics of Hf₂O films according to a conventional process and according to this experimental example. The leakage current characteristics were measured in a dynamic random access memory (DRAM) semiconductor device with a 120 nm design rule. As shown in FIG. 7, it can be seen that a thin film formed according to an embodiment of the invention has far superior leakage current characteristics than a film formed according to the conventional process. This is because impurities such as OH radicals and oxygen vacancies are generated in a large amount in a thin film formed according to a conventional process, as described above. However, according to embodiments of the invention, since OH radicals and oxygen vacancies are significantly removed by oxygen (O) supplied when the second reactant is transformed into a plasma state, a thin film with excellent electrical properties can be formed.

As apparent from the above descriptions, according to embodiments of the invention, a thin film with excellent step coverage can be uniformly formed in a thin thickness regardless of topography of a substrate intended for film formation. Furthermore, by using both a compound with good surface adsorptivity and a compound with poor surface adsorptivity, a thin film with excellent electrical properties can be deposited in a short time. In particular, in the case of forming a thin film for a metal dielectric film, even if a Cl-containing material is used as a source material, a thin film with excellent electric properties can be formed.

In addition, according to embodiments of the invention, since direct plasma is applied, relatively simple processing equipment is used for thin film formation as compared to application of remote plasma. Furthermore, use of such direct plasma reduces energy loss, and thus, increases process efficiency.

There are many ways to practice the invention. What follows are exemplary, nonlimiting descriptions of embodiments of the invention.

According to an embodiment of the invention, there is provided a method of forming a thin film using ALD, in which a first reactant having good surface adsorptivity for a source material and a second reactant having poor surface adsorptivity for the source material are used as reactants to the source material, and after the second reactant is fed into the reaction chamber, a radio frequency is applied to a reaction chamber so as to transform the second reactant into a plasma state.

Since the first reactant has good surface adsorptivity for the source material, the first reactant easily reacts with the source material adsorbed on a substrate or on the thin film that was previously deposited. Therefore, a process duration can be reduced. The second reactant with poor surface adsorptivity for the source material is fed into the reaction chamber and then directly transformed into a plasma state in the reaction chamber.

For example, a hydrogen (H)-containing material may be used as the first reactant and an H-free material may be used as the second reactant. In this case, since the H-free material is fed and then directly activated into a plasma state, it is easy to remove an H group from a thin film. Furthermore, the reactivity of the second reactant is increased, when compared to use of a remote plasma gas. Therefore, it is possible to prevent or inhibit generation of impurities containing an OH radical or the like in a thin film.

More specifically, suppose that the source material contains a chlorine (Cl) group. Again, it is preferable to use an H-containing material as the first reactant and an H-free material as the second reactant. Since an H-containing reactant has good surface adsorptivity for a Cl-containing source material, it is easy to form HCl by reaction of the Cl group contained in the source material with the H group contained in the reactant.

In particular, since the second reactant contains no H groups, it is not fully adsorbed on the source material even when activated into a plasma state. For example, when HfCl₄ is used as the source material to form an HfO₂ film, even if O₂ as a reactant is fed and then activated into a plasma state by radio frequency application, only a slight formation of a thin film occurs. This is because a functional group capable of removing a Cl group is not contained in the reactant. Therefore, use of only O₂ as a reactant can prevent formation of impurities, but is not helpful in terms of productivity.

As can be seen from the above descriptions, embodiments of the invention resolve problems caused in using a material with good surface adsorptivity for a source material and also in using a material with poor surface adsorptiviy for a source material. That is, not only can formation of impurities in a thin film be prevented, but productivity also increases, thereby reducing a process duration.

According to another embodiment of the invention, there is provided a method of forming a thin film using ALD that includes processes such as feeding a source material into a reaction chamber; purging the source material from the reaction chamber; feeding, into the reaction chamber, a material with good surface adsorptivity for the source material as a first reactant and a material with poor surface adsorptivity for the source material as a second reactant, and applying a radio frequency to the reaction chamber to transform the second reactant into a plasma state.

According to specific embodiments of the present invention, the supply of the second reactant into the reaction chamber may be continued during one ALD cycle. This is because the second reactant reacts only slightly with the source material, as described above. The second reactant may be O₂ or N₂.

The first reactant supply and the second reactant supply may be performed sequentially. That is, purging may be carried out after a predetermined time from the supply of the first reactant into the reaction chamber, and then the supply of the second reactant may be carried out. Such an additional purging process performed after the supply of the first reactant may slightly increase process duration when compared to a conventional process. However, it is advantageous in that a thin film with excellent electrical properties can be formed.

While the invention has been particularly shown and described with reference to exemplary embodiments thereof, it will be understood by those of ordinary skill in the art that various changes in form and details may be made therein without departing from the spirit and scope of the invention as defined by the following claims.

We claim:

1. A method of forming a thin film on a substrate using atomic layer deposition (ALD), the method comprising:
supplying a first reactant having good surface adsorptivity for a source material to a reaction chamber;
supplying a second reactant having poor surface adsorptivity for the source material to the reaction chamber; and
after supplying the second reactant, transforming the second reactant into a plasma state by applying a radio frequency to the reaction chamber.

2. The method according to claim 1, wherein the source material is a chlorine (Cl)-containing metal compound.

3. The method according to claim 2, wherein supplying the first reactant comprises supplying a hydrogen-containing material and supplying the second reactant comprises supplying an H-free material.

4. The method according to claim 3, wherein supplying the hydrogen-containing material comprises supplying H₂O, supplying the H-free material comprises supplying O₂, and forming the thin film comprises forming a metal oxide film.

5. The method according to claim 4, wherein the metal oxide film comprises a mono-metal oxide or a multi-metal oxide.

6. The method according to claim 5, wherein the mono-metal oxide is one selected from the group consisting of Al₂O₃, TiO₂, Ta₂O₅, ZrO₂, HfO₂, Nb₂O₅, CeO₂, Y₂O₃, SiO₂, In₂O₃, RuO₂, and IrO₂.

7. The method according to claim 5, wherein the multi-metal oxide is one selected from the group consisting of SrTiO₃, PbTiO₃, SrRuO₃, CaRuO₃, (Ba,Sr) TiO₃, Pb (Zr,Ti)O₃, (Pb,La) (Zr,Ti)O₃, (Sr,Ca) RuO₃, In₂O₂ doped with Sn, In₂O₃ doped with Fe, and In₂O₃ doped with Zr.

8. The method according to claim 2, wherein the thin film is a metal nitride film, the first reactant is NH₃, and the second reactant is N₂.

9. The method according to claim 8, wherein the metal nitride film is chosen from the group consisting of a TiN film, a TaN film, and a WN film.

10. The method according to claim 2, wherein the thin film is a nitride oxide film, the first reactant is H₂O, and the second reactant is N₂.

11. The method according to claim 1, wherein the source material is a metal organic compound.

12. The method according to claim 11, wherein the first reactant is H₂O or O₃ and the second reactant is N₂.

13. A method of forming a thin film on a substrate in a reaction chamber using ALD, the method comprising:
supplying a source material into the reaction chamber;
purging the source material from the reaction chamber;
supplying, into the reaction chamber, a first reactant having a first surface adsorptivity for the source material and a second reactant with a second surface adsorptivity for the source material, the second adsorptivity less than the first adsorptivity; and
transforming the second reactant into a plasma state.

14. The method according to claim 13, wherein supplying the second reactant comprises continuously supplying the second reactant from a time of supplying the source material to a time of transforming the second reactant into a plasma state.

15. The method according to claim 14, wherein the second reactant is chosen from the group consisting of O₂ and N₂.

16. The method according to claim 13, wherein supplying the first reactant and the second reactant comprises:
purging the reaction chamber of the first reactant before supplying the second reactant.

17. The method according to claim 13, further comprising:
after transforming the second reactant into the plasma state, purging the reaction chamber.

18. The method according to claim 17, wherein the processes of supplying the source material, purging the source material, supplying the first and second reactants, transforming the second reactant, and purging the reaction chamber are repeated several times.

19. The method according to claim 13, wherein the source material is a Cl-containing metal compound.

20. The method according to claim 19, wherein the first reactant is an H-containing material and the second reactant is an H-free material.

21. The method according to claim 20, wherein the thin film is a metal oxide film, the first reactant is H₂O, and the second reactant is O₂.

22. The method according to claim 20, wherein the thin film is a metal nitride film, the first reactant is NH₃, and the second reactant is N₂.

23. The method according to claim 20, wherein the thin film is a nitride oxide film, the first reactant is H₂O, and the second reactant is N₂.

24. The method according to claim 13, wherein the source material is a metal organic compound.

25. The method according to claim 24, wherein the first reactant is chosen from the group consisting of H₂O and O₃ and the second reactant is N₂.
